(19) United States
(12) Patent Application Publication
(10) Pub. No.: US 2015/0261252 A1
(43) Pub. Date: Sep. 17, 2015

(54) THIN FILM TOUCH PANEL STRUCTURE

(71) Applicants: Interface Optoelectronics (Shenzhen) Co., Ltd., Shenzhen City (CN); GENERAL INTERFACE SOLUTION LIMITED, MIAOLI COUNTY (TW)

(72) Inventors: Nan-Tsun Kuo, MIAOLI COUNTY (TW); Chia-Ming Hsieh, MIAOLI COUNTY (TW); Tzu-Hsiang Lin, MIAOLI COUNTY (TW); Yen-Heng Huang, MIAOLI COUNTY (TW)

(21) Appl. No.: 14/727,849

(22) Filed: Jun. 1, 2015

(30) Foreign Application Priority Data
Feb. 13, 2015 (CN) 201510083375.3

(51) Int. Cl. G06F 1/16; G06F 3/041; H05K 1/03; H05K 1/02; H05K 1/09

(52) U.S. Cl. CPC G06F 1/16; H05K 1/0274; H05K 1/09; H05K 1/0326; G06F 3/041; H05K 2201/0145; H05K 2201/0326; H05K 2201/0112; H05K 2201/0195; G06F 2203/04107

(57) ABSTRACT

A thin film touch panel structure includes a sensor film, a cover glass having a top surface and a bottom surface, and an optical adhesive layer between the sensor film and the cover glass. The sensor film is adhered to the bottom surface of the cover glass through the optical adhesive layer. The optical adhesive layer or any layer in the sensor film provides a sharp cutoff of UV light with a wavelength below 400 nm.

### CROSS REFERENCE TO RELATED APPLICATION

This application claims priority from China Patent Application No. CN 201510083375.3, filed Feb. 13, 2015. The entirety of the above-mentioned patent application is hereby incorporated by reference herein and made a part of this specification.

### BACKGROUND OF THE INVENTION

1. Field of the Invention

The present invention relates to touch panel technology, and particularly relates to an improved thin film touch panel structure capable of passing anti-UV reliability test.

2. Description of the Prior Art

As known in the art, thin film touch panel can be divided into bilayer sensor G/F/F stack configuration and a single-layer sensor G/F stack configuration. Typically, a sensor film, on which an indium tin oxide (ITO) transparent electrode film is formed, is bonded to a glass by using optical clear adhesive (OCA).

Because the touch panel devices have been widely used in various applications including circumstances with severe environmental conditions, it is difficult to satisfy a variety of product specifications with conventional material combinations, for example, the anti-UV reliability test for automotive display panels. After prolonged UV exposure, bubble-like defects are formed in the sensor film, resulting in poor appearance of the touch panel.

In light of the above, there is still a need for an improved thin film touch panel capable of solving the above-mentioned deficiencies and disadvantages of the prior art.

### SUMMARY OF THE INVENTION

Therefore, a primary object of the present invention to provide an improved thin film touch panel structure, which uses an optical layer capable of blocking ultraviolet (UV) rays, to thereby avoid the impact of UV-induced deterioration and yellowing (may cause reduced transparency and poor appearance), and peeling of hard coat of the sensor film, and increase resistance to extreme conditions.

Another object of the present invention is to provide a touch panel having a G/F or G/F/F stack configuration. A film structure in the G/F or G/F/F stack has anti-UV property, and can cut off UV with a wavelength of 400 nm or less.

According to one aspect of the invention, a thin film touch panel comprises a sensor film; a cover glass having a top surface and a bottom surface; and an optical adhesive layer disposed between the sensor film and the cover glass, wherein the sensor film is bonded to the bottom surface of the cover glass by the optical adhesive layer, and wherein the optical adhesive layer or any layer in the sensor film is able to cut off UV light with a wavelength of 400 nm or less.

The embodiments of the present invention utilize the optical adhesive layer with UV cutting ability to protect each layer in the stack structure, which can effectively avoid UV-induced deterioration, yellowing (may cause reduced transparency and poor appearance), and peeling of hard coat of the sensor film, and increase resistance to extreme conditions.

According to another aspect of the invention, a thin film touch panel comprises a cover glass; a first sensor film; a first optical adhesive layer between the first sensor film and the cover glass; a second sensor film; and a second optical adhesive layer between the second sensor film and the cover glass, wherein the first optical adhesive layer or the second optical adhesive layer is able to cut off UV light with a wavelength of 400 nm or less.

According to still another aspect of the invention, a thin film touch panel comprises at least one sensor film comprising an indium tin oxide (ITO) transparent electrode, a plastic substrate, a hard coat layer, and an optical adjust layer; a cover glass having a top surface and a bottom surface; and an optical adhesive layer disposed between the sensor film and the cover glass, wherein the sensor film is bonded to the bottom surface of the cover glass by the optical adhesive layer, wherein at least one of the optical adhesive layer, the ITO transparent electrode, the plastic substrate, the hard coat layer, or the optical adjust layer is able to cut off UV light with a wavelength of 400 nm or less.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic, cross-sectional diagram showing an exemplary thin film touch panel according to one embodiment of the invention.

FIG. 2 is a schematic, cross-sectional diagram showing an exemplary thin film touch panel according to another embodiment of the invention.

### DETAILED DESCRIPTION

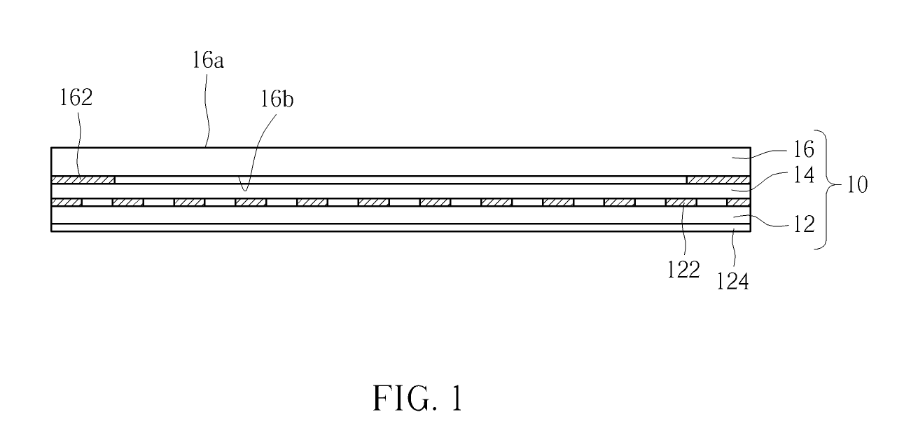

Please refer to FIG. 1. FIG. 1 is a schematic, cross-sectional diagram showing an exemplary thin film touch panel according to one embodiment of the invention. According to the illustrative embodiment, the exemplary thin film touch panel has a G/F stack configuration.

As shown in FIG. 1, the present invention thin film touch panel 10, taking a G/F stack structure as an example, comprises a sensor film 12, an optical adhesive layer 14, and a cover glass 16. According to the illustrative embodiment of the invention, a layer of indium tin oxide (ITO) transparent electrode 122 is formed on the sensor film 12. The optical adhesive layer 14 is an optically clear adhesive (OCA) film.

According to the illustrative embodiment of the present invention, the sensor film 12 may comprise a plastic substrate, e.g., polyethylene terephthalate (PET), but is not limited thereto.

According to the illustrative embodiment of the present invention, the sensor film 12 may also include a hard coat layer 124 on the outermost side of the sensor film 12. For example, the hard coat layer 124 may comprise silicon dioxide or acrylic, but is not limited thereto.

According to the illustrative embodiment of the present invention, the sensor film 12 may also comprise an optical adjust layer (not shown), but is not limited thereto.

According to the illustrative embodiment of the invention, the sensor film 12 is bonded to a bottom surface 16b of the cover glass 16 by the optical adhesive layer 14. From the top surface 16a of the cover glass 16, the user inputs data through user's gestures or touch operations.

According to the illustrative embodiment of the invention, the cover glass 16 may be subjected to anti-reflection treatment, anti-glare treatment, anti-stain treatment, anti-bacterial treatment, or anti-UV treatment. Alternatively, a protective layer (not shown), e.g., an anti-reflection layer, an anti-glare layer, an anti-stain layer, an anti-bacterial layer, or an anti-UV layer, may be provided on the top surface 16a of the cover glass 16. In the periphery of the bottom surface 16b of the cover glass 16, an ink layer 162 may be disposed to surround the visible area of the touch panel.

As mentioned earlier, after prolonged UV exposure, bubble-like defects are formed in the prior art sensor film, resulting in poor appearance of the touch panel.

To solve this problem, according to the illustrative embodiment of the invention, the optical adhesive layer 14 has UV barrier or UV absorption properties, e.g., which can cut off ultraviolet light with a wavelength of 400 nm or less. In other embodiments, any layer of the sensor film 12 may have UV blocking or absorbing properties.

According to the illustrative embodiment of the invention, the UV transmittance of the optical adhesive layer 14 at 400 nm or less is close to 0. In other words, UV penetration below 400 nm is almost completely blocked. According to the illustrative embodiment of the invention, the optical adhesive layer 14 may contain UV absorbers, to absorb UV rays having a wavelength of 400 nm or less. However, it should be understood by those skilled in the art that in addition to the above UV absorbers, the anti-UV effect may be achieved by physical ways.

The illustrative embodiment of the present invention uses the optical adhesive layer 14 with UV cutting ability to protect each layer in the stack structure, which can effectively avoid UV-induced deterioration, yellowing (may cause reduced transparency and poor appearance) , and peeling of hard coat of the sensor film, and increase resistance to extreme conditions.

Further, the introduction of the optical adhesive layer 14 with UV cutting ability does not affect the overall optical properties of the touch panel (L*a*b* color difference Delta E <0.5) and its functionality.

The present invention touch panel module can pass the anti-UV reliability test implemented under the following strict conditions: exposure to 340 nm UV-A (0.63W/m2/nm) at 60° C. for 4 hours, and then moisture exposure at 50° C. in a moisture environment for 4 hours, 12 to 24 cycles.

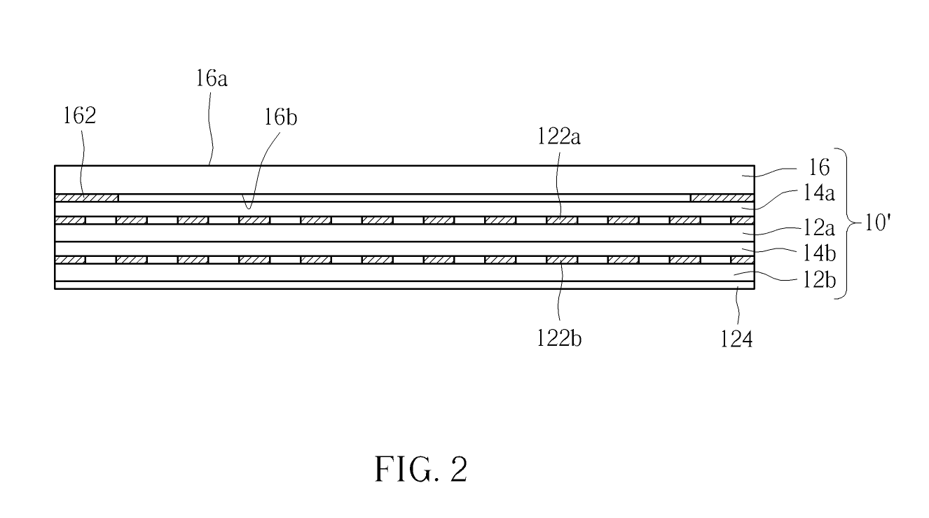

Please refer to FIG. 2. FIG. 2 is a schematic, cross-sectional diagram showing an exemplary thin film touch panel according to another embodiment of the invention. According to the illustrative embodiment, the exemplary thin film touch panel in FIG. 2 has a G/F/F stack configuration.

As shown in FIG. 2, the present invention thin film touch panel 10′, taking a G/F/F stack structure as an example, comprises a first sensor film 12a having thereon an ITO transparent electrode 122a, a first optical adhesive layer 14a, a second sensor film 12b having thereon an ITO transparent electrode 122b, a second optical adhesive layer 14b, and a cover glass 16.

According to the illustrative embodiment of the present invention, the first and second sensor films 12a and 12b may comprise a plastic substrate, e.g., polyethylene terephthalate (PET), but is not limited thereto.

According to the illustrative embodiment of the invention, the first sensor film 12a is bonded to a bottom surface 16b of the cover glass 16 by the first optical adhesive layer 14a. From the top surface 16a of the cover glass 16, the user inputs data through user's gestures or touch operations. the second sensor film 12b is bonded to a bottom surface of the first sensor film 12a by the second optical adhesive layer 14b.

According to the illustrative embodiment of the present invention, the second sensor film 12b may also include a hard coat layer 124 on the outermost side of the second sensor film 12b. For example, the hard coat layer 124 may comprise silicon dioxide or acrylic, but is not limited thereto.

According to the illustrative embodiment of the invention, the cover glass 16 may be subjected to anti-reflection treatment, anti-glare treatment, anti-stain treatment, anti-bacterial treatment, or anti-UV treatment. Alternatively, a protective layer (not shown), e.g., an anti-reflection layer, an anti-glare layer, an anti-stain layer, an anti-bacterial layer, or an anti-UV layer, may be provided on the top surface 16a of the cover glass 16. In the periphery of the bottom surface 16b of the cover glass 16, an ink layer 162 may be disposed to surround the visible area of the touch panel.

According to the illustrative embodiment of the invention, the aforesaid optical adhesive layer has UV barrier or UV absorption properties, e.g., which can cut off ultraviolet light with a wavelength of 400 nm or less.

According to the illustrative embodiment of the invention, the UV transmittance of the first optical adhesive layer 14a or second optical adhesive layer 14b at 400 nm or less is close to 0. In other words, UV penetration below 400 nm is almost completely blocked. According to the illustrative embodiment of the invention, the first optical adhesive layer 14a or second optical adhesive layer 14b may contain UV absorbers, to absorb UV rays having a wavelength of 400 nm or less. According to the embodiment of the invention, the first optical adhesive layer 14a and second optical adhesive layer 14b both contain UV absorbers, to absorb UV rays having a wavelength of 400 nm or less.

Those skilled in the art should understand that the present invention is suitable for application in G/F stack configuration having a single-side ITO (SITO) conductive structure, and said G/F/F stack structure having any layer therein with anti UV effects. The single-side ITO (SITO) conductive structure refers to that the sensor electrodes are disposed in the same layer. In other words, the present invention is not limited to only the optical adhesive layer has anti-UV effect.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A thin film touch panel, comprising:
a sensor film;
a cover glass having a top surface and a bottom surface; and
an optical adhesive layer disposed between the sensor film and the cover glass, wherein the sensor film is bonded to the bottom surface of the cover glass by the optical adhesive layer, and wherein the optical adhesive layer or any layer in the sensor film is able to cut off ultraviolet (UV) light with a wavelength of 400 nm or less.

2. The thin film touch panel according to claim 1, wherein the optical adhesive layer comprises UV absorbers.

3. The thin film touch panel according to claim 1, wherein an indium tin oxide (ITO) transparent electrode is formed on the sensor film.

4. The thin film touch panel according to claim 1, wherein the sensor film comprise a plastic substrate, and wherein the plastic substrate comprises polyethylene terephthalate (PET).

5. The thin film touch panel according to claim 1, wherein the sensor film comprises a hard coat layer.

6. The thin film touch panel according to claim 5, wherein the hard coat layer comprises silicon dioxide or acrylic.

7. The thin film touch panel according to claim 1, wherein the sensor film comprises an optical adjust layer.

8. A thin film touch panel, comprising:
a cover glass;
a first sensor film;
a first optical adhesive layer between the first sensor film and the cover glass;
a second sensor film; and
a second optical adhesive layer between the second sensor film and the cover glass, wherein the first optical adhesive layer or the second optical adhesive layer is able to cut off ultraviolet (UV) light with a wavelength of 400 nm or less.

9. The thin film touch panel according to claim 8, wherein the first optical adhesive layer, the second optical adhesive layer, or a combination thereof comprises UV absorbers.

10. A thin film touch panel, comprising:
at least one sensor film comprising an indium tin oxide (ITO) transparent electrode, a plastic substrate, a hard coat layer, and an optical adjust layer;
a cover glass having a top surface and a bottom surface; and
an optical adhesive layer disposed between the sensor film and the cover glass, wherein the sensor film is bonded to the bottom surface of the cover glass by the optical adhesive layer, wherein at least one of the optical adhesive layer, the ITO transparent electrode, the plastic substrate, the hard coat layer, or the optical adjust layer is able to cut off ultraviolet (UV) light with a wavelength of 400 nm or less.
